(19) United States
(12) Patent Application Publication
(10) Pub. No.: US 2017/0002807 A1
(43) Pub. Date: Jan. 5, 2017

(54) ELECTRIC PUMP

(71) Applicant: KYB CORPORATION, Tokyo (JP)

(72) Inventor: Yoshinori KOGISO, Gifu (JP)

(73) Assignee: KYB Corporation, Tokyo (JP)

(21) Appl. No.: 15/125,593

(22) PCT Filed: Apr. 2, 2015
(86) PCT No.: PCT/JP2015/060504

§ 371 Date: Sep. 13, 2016

(30) Foreign Application Priority Data
Apr. 16, 2014 (JP) 2014-084957

(51) Int. Cl. F04B 53/08; H05K 7/20; F04B 49/06; H02K 11/33; F01M 1/02; F04B 17/00

(52) U.S. Cl. CPC F04B 53/08; F01M 1/02; F04B 17/00; F04B 49/065; H02K 11/33; H05K 7/20909

(57) ABSTRACT

An electric pump includes a pump configured to suck, pressurize and discharge working fluid, a motor coupled with the pump and configured to drive the pump, a motor controller arranged laterally to the motor and configured to control the drive of the motor, and a cooling unit arranged between the motor and the motor controller and configured to cool the motor controller by a refrigerant circulating inside. The cooling unit includes a raised portion projecting into an inner space of the motor controller and formed with a flow passage for the circulation of the refrigerant inside.

### TECHNICAL FIELD

The present invention relates to an electric pump.

### BACKGROUND ART

An electric oil pump including a pump for pressurizing oil, a motor coupled to the pump and a motor controller directly fixed to one end of the motor is disclosed as an electric pump in JP2011-94553A.

In this electric oil pump, a cooling fin is provided in the motor controller to radiate heat generated in the motor controller.

### SUMMARY OF INVENTION

However, in the above conventional technology, not only heat generated inside, but also the heat of the pump for sucking and discharging the oil having an increased temperature are transferred to the motor controller via the motor. Thus, the temperature of an electronic circuit arranged in the motor controller increases and an output of the motor and an operation time may be limited.

The present invention was developed in view of such a technical problem and aims to suppress a temperature increase of an electronic circuit arranged in a motor controller and enable a motor to operate with a higher output for a longer time.

According to one aspect of the present invention, an electric pump for discharging working fluid includes: a pump configured to suck, pressurize and discharge the working fluid; a motor coupled with the pump and configured to drive the pump; a motor controller arranged laterally to the motor and configured to control the drive of the motor; and a cooling unit arranged between the motor and the motor controller and configured to cool the motor controller by a refrigerant circulating inside. The cooling unit includes a raised portion projecting into an inner space of the motor controller, the raised portion being formed with a flow passage for the circulation of the refrigerant inside.

### BRIEF DESCRIPTION OF DRAWINGS

FIG. 1 is a side view of an electric pump according to an embodiment of the present invention,

FIG. 2 is a sectional view along line II-II of FIG. 1,

FIG. 3 is a sectional view along line III-III of FIG. 1,

FIG. 4 is a sectional view along line IV-IV of FIG. 2,

FIG. 5 is a sectional view along line V-V of FIG. 2, and

FIG. 6 is an enlarged view of a raised portion of FIG. 2.

### DESCRIPTION OF EMBODIMENT

Hereinafter, an electric pump 100 according to an embodiment of the present invention is described with reference to the drawings.

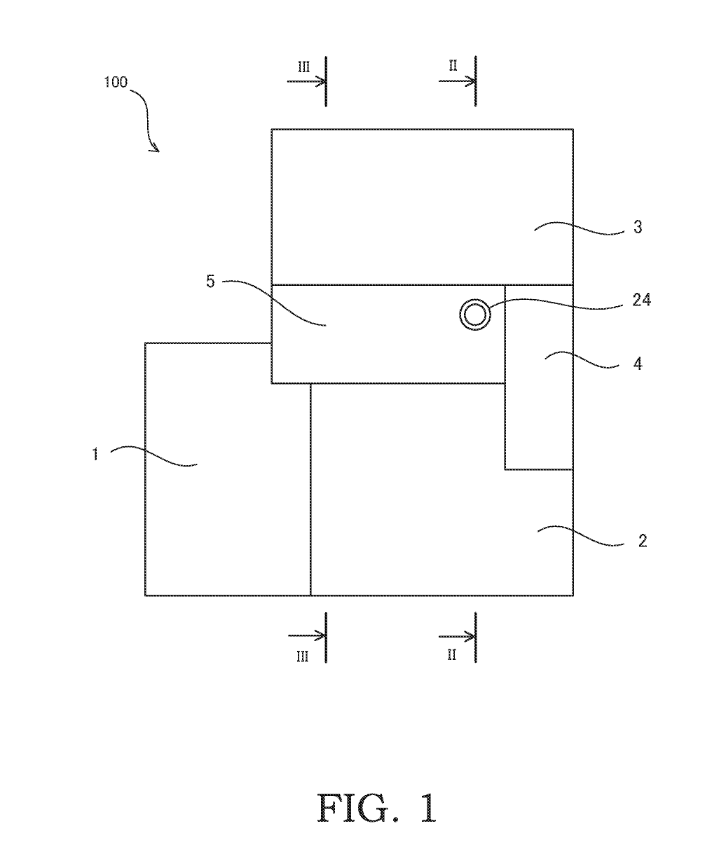

The electric pump 100 shown in FIG. 1 is mounted in an engine or a transmission of an automotive vehicle and used to supply oil to a lubricating portion and supply a hydraulic pressure to a hydraulic device driven by the hydraulic pressure.

The electric pump 100 includes a pump 1 configured to suck, pressurize and discharge hydraulic oil as working fluid, a motor 2 coupled with the pump 1 on one side in a drive shaft direction and configured to drive the pump 1, and a motor controller 3 arranged laterally to (upwardly of in FIG. 1) the motor 2 and configured to control the drive of the motor 2.

The pump 1 includes unillustrated suction port and discharge port, pressurizes hydraulic oil sucked through the suction port and supplies the pressurized hydraulic oil to an unillustrated hydraulic device and the like from the discharge port. The pump 1 includes an unillustrated driven shaft to be driven by the motor 2 and sucks and discharges the hydraulic oil by the rotation or reciprocation of the driven shaft. The pump 1 may be any pump such as a piston pump, a gear pump, a centrifugal pump or a plunger pump as long as working fluid is sucked and discharged by the rotation or reciprocation of a driven shaft.

The motor 2 includes an unillustrated drive shaft which is rotated or reciprocated by the supply of power, and the drive shaft is coupled to the driven shaft of the pump 1 on one side in the drive shaft direction. A casing of the motor 2 is connected to a casing of the pump 1 on the one side in the drive shaft direction by unillustrated connection means. The motor 2 may be of any form as long as including a drive shaft which is rotated or reciprocated by the supply of power. Further, the casing of the motor 2 may be integrally formed to the casing of the pump 1.

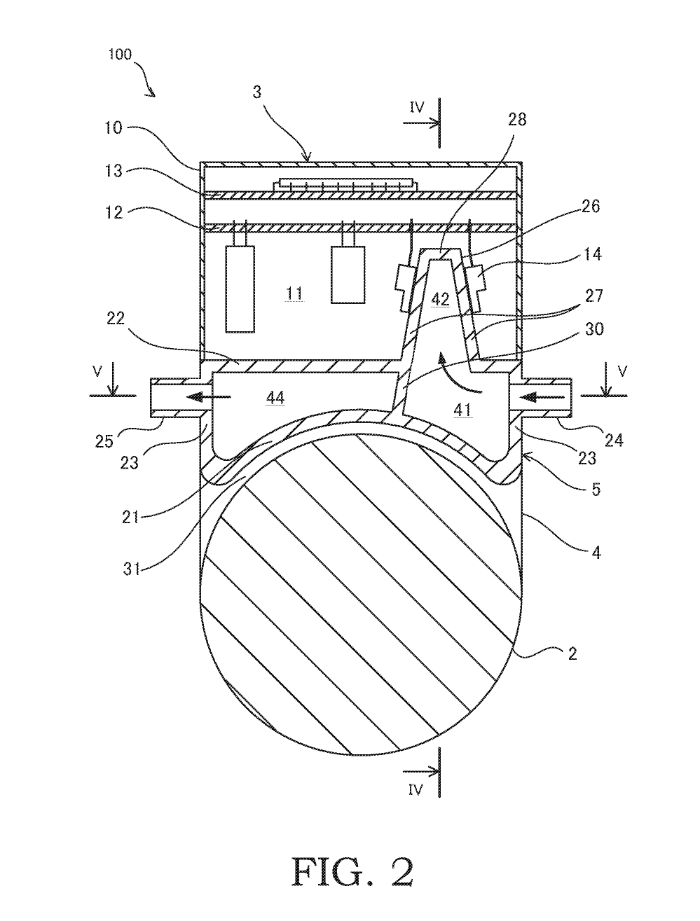

Next, the motor controller 3 is described with reference to FIG. 2. FIG. 2 is a sectional view along line II-II of FIG. 1, wherein a cross-section of the motor 2 is not shown.

The motor controller 3 includes a drive circuit board 12 arranged on the side of the motor 2 and a control circuit board 13 parallel to the drive circuit board 12 and arranged on a side opposite to the motor 2 with respect to the drive circuit board 12 in a casing 10. The drive circuit board 12 is a board for supplying a drive current to the motor 2 and the control circuit board 13 is a board for controlling the drive of the motor 2.

Heat generating and relatively large circuit elements such as transistors, a capacitor and a coil are mounted on the drive circuit board 12, and an IC chip such as a microcomputer is mounted on the control circuit board 13. The drive circuit board 12 and the control circuit board 13 are connected to an external power source and other control devices via unillustrated connectors and connected to the motor 2 via an unillustrated busbar provided in a connecting portion 4 for connecting the motor 2 and the motor controller 3.

The connecting portion 4 is a member for not only connecting the motor 2 and the motor controller 3, but also fixing the motor controller 3 to the motor 2. One end of the connecting portion 4 is connected to the motor controller 3 and the other end is connected to the motor 2. The connecting portion 4 is connected to the motor 2 in a part near the other side of the motor 2 in the drive shaft direction opposite to the one side in the drive shaft direction where the pump 1 is coupled to the motor 2. Specifically, the connecting portion 4 is connected to the motor 2 in a part distant from the part where the pump 1 is coupled to the motor 2. The heat of the pump 1 is transferred to the motor controller 3 via the motor 2 and the connecting portion 4, but a heat transfer path is long since the pump 1 and the connecting portion 4 are arranged at positions distant from each other. As a result, the heat of the pump 1 is difficult to transfer to the motor controller 3. The connecting portion 4 may be integrally formed to the casing of the motor 2, the casing 10 of the motor controller 3 or a cooling unit 5 to be described later.

The cooling unit 5 for cooling the motor controller 3 by a refrigerant circulating inside is linked to the motor controller 3. The cooling unit 5 is arranged between the motor controller 3 and the motor 2 and includes a heat insulating wall 21 facing toward the motor 2, a cooling wall 22 facing toward the motor controller 3 and a side wall 23 connecting the heat insulating wall 21 and the cooling wall 22. A circulation space in which the refrigerant circulates is formed in an inner space enclosed by the heat insulating wall 21, the cooling wall 22 and the side wall 23. The side wall 23 is provided with an introduction port 24 for introducing the refrigerant into the circulation space and a discharge port 25 for discharging the refrigerant.

The heat insulating wall 21 is formed into a curved surface in conformity with the outer shape of the casing of the motor 2 and arranged to form a predetermined clearance 31 as a heat insulating layer between the heat insulating wall 21 and the casing of the motor 2. By providing the predetermined clearance 31, the heat of the motor 2 and the heat of the pump 1 are prevented from being directly transferred to the cooling unit. To enhance a heat insulation property, a heat insulating material may be provided between the heat insulating wall 21 and the casing of the motor 2. Alternatively, cooling air or traveling air may be introduced to the clearance 31.

The cooling wall 22 doubles as a sealing member for sealing an opening end of the casing 10 of the motor controller 3. That is, the casing 10 of the motor controller 3 is linked to the cooling unit 5 by unillustrated linking means. Thus, an inner space 11 extending from the drive circuit board 12 toward the motor 2 is particularly cooled by the refrigerant via the cooling wall 22.

The cooling wall 22 is formed with a raised portion 26 projecting into the inner space 11 in the motor controller 3. As shown in FIG. 2, the raised portion 26 includes two inclined walls 27 inclined with respect to a direction perpendicular to the drive circuit board 12 and is shaped to narrow a distance between the two inclined walls 27 toward the drive circuit board 12. In the present embodiment, a connecting wall 28 is provided to connect end parts of the inclined walls 27 on the side of the drive circuit board 12. The end parts of the inclined walls 27 may be shaped to be directly connected without providing the connecting wall 28.

By providing the cooling unit 5 with the raised portion 26 projecting into the inner space 11, the inner space 11 extending from the drive circuit board 12 toward the cooling unit 5 is enlarged. This enlarged inner space 11 becomes a space in which relatively large circuit elements such as a coil and a capacitor are arranged in a concentrated manner and is effectively utilized.

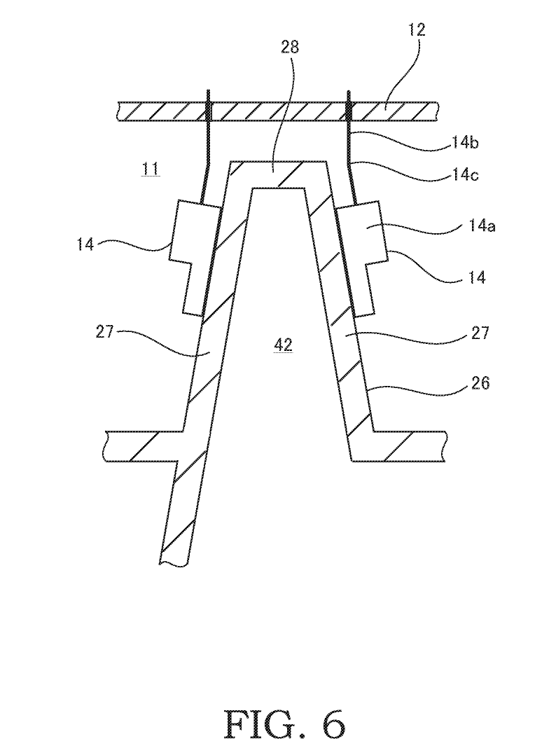

Out of the circuit elements arranged on the drive circuit board 12, transistors 14 are fixed to the inclined walls 27. A fixed state of the transistors 14 is described with reference to FIG. 6. FIG. 6 is an enlarged view enlargedly showing the periphery of the raised portion 26 of FIG. 2.

A main body portion 14a of the transistor 14 is fixed by fixing means such as a screw in a state held in contact with an inclined surface of the inclined wall 27. On the other hand, the tip of a terminal portion 14b extending from the main body portion 14a of the transistor 14 is fixed to the drive circuit board 12 such as by soldering. Since an angle between the inclined wall 27 and the drive circuit board 12 is not a right angle as described above, a moderate bent portion 14c is formed at an intermediate position of the terminal portion 14b. Thus, a part of the terminal portion 14b close to the main body portion 14a is parallel to the inclined surface of the inclined wall 27 and a part of the terminal portion 14b close to the drive circuit board 12 is perpendicular to the drive circuit board 12.

Since the terminal portion 14b of the transistor 14 includes the bent portion 14c, even if an interval between the drive circuit board 12 to which the terminal portion 14b of the transistor 14 is fixed and the inclined wall 27 to which the main body portion 14a of the transistor 14 is fixed changes due to a thermal expansion difference, this change is absorbed by increasing or decreasing an angle of the bent portion 14c. Thus, even if the thermal expansion difference occurs, a force acting on a soldered part of the drive circuit board 12 and the terminal portion 14b is reduced.

In the present embodiment, two inclined walls 27 are provided. If there are many transistors 14, these can be arranged in a compact manner. In the case of a few transistors 14, the transistors 14 may be fixed only to one inclined wall 27 and the other inclined wall 27 may be a wall perpendicular to the drive circuit board 12.

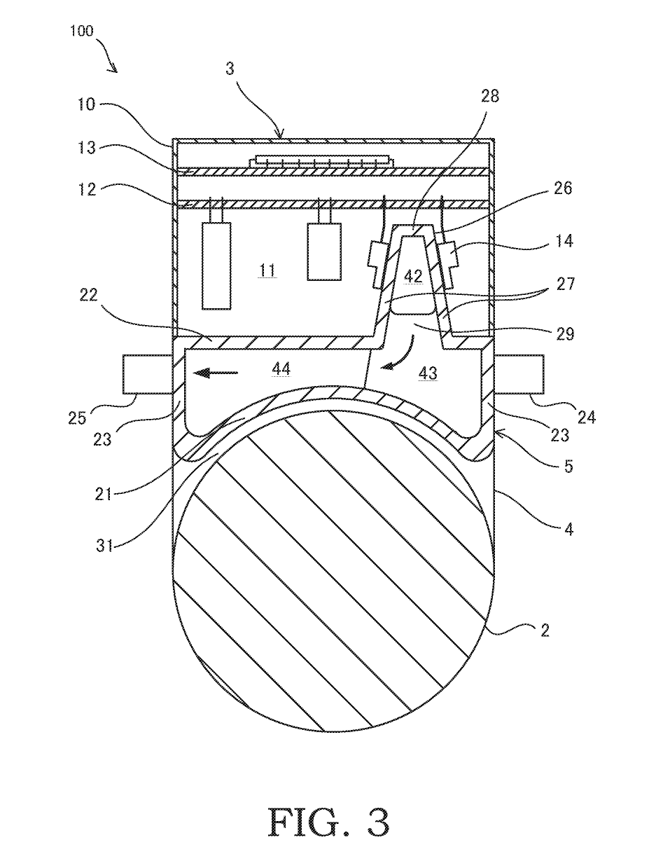

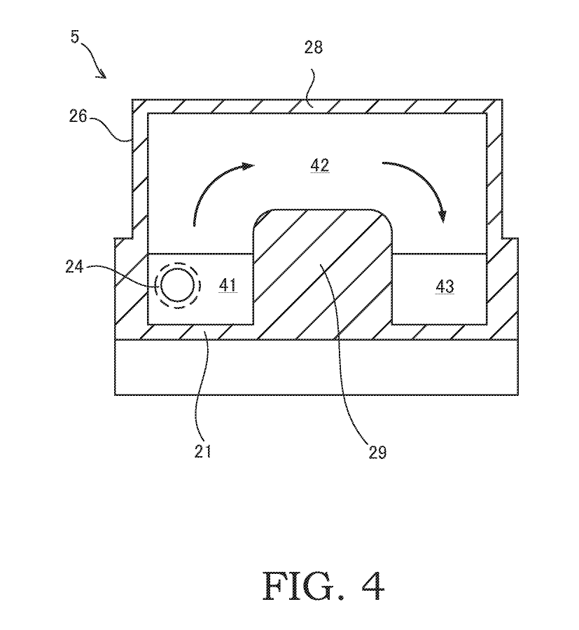

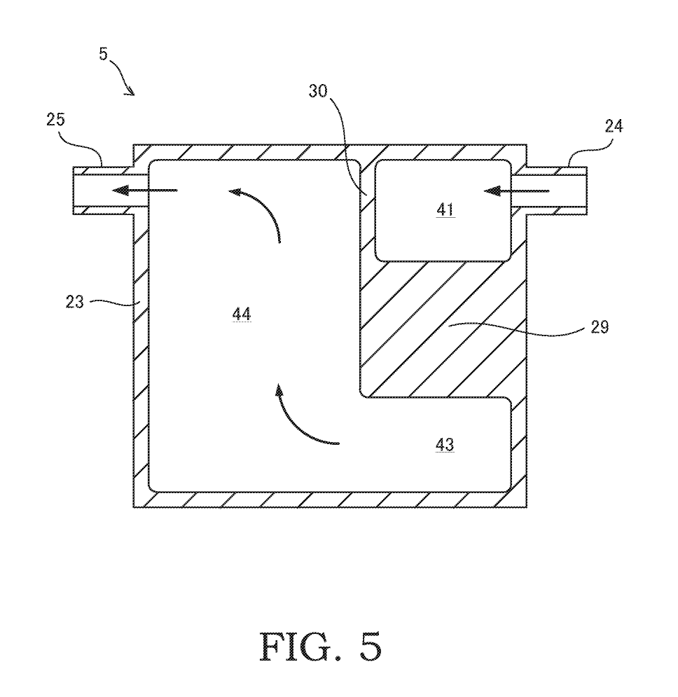

Next, the circulation space in the cooling unit 5 in which the refrigerant circulates is described with reference to FIGS. 2 to 5. FIG. 3 is a sectional view along line III-III of FIG. 1, wherein a cross-section of the motor 2 is not shown. FIGS. 4 and 5 are respectively sectional views along lines IV-IV, V-V of FIG. 2, wherein components other than the cooling unit 5 are not shown. Arrows in each figure show the flow of the refrigerant.

The circulation space in the cooling unit 5 includes an inlet space 41 where the introduction port 24 provided on the side wall 23 is open, a raised portion inner space 42 formed in the raised portion 26 and connected to the inlet space 41, a flat space 44 where the discharge port 25 provided on the side wall 23 is open, and a connection space 43 connecting the raised portion inner space 42 and the flat space 44.

As shown in FIGS. 2 and 4, the inlet space 41 is a space enclosed by the side wall 23 and a guide portion 29 and an inner wall 30 provided in the cooling unit 5. As shown in FIG. 4, the guide portion 29 is a bulging portion formed to extend from the heat insulating wall 21 toward the raised portion 26. By providing the guide portion 29, the refrigerant flowing into from the introduction port 24 flows toward the motor controller 3 without flowing along the cooling wall 22 and the heat insulating wall 21. As shown in FIG. 2, the inner wall 30 is provided below and near the inclined wall 27 distant from the introduction port 24 out of the inclined walls 27 of the raised portion 26 and connected to the cooling wall 22, the heat insulating wall 21, the side wall 23 and the guide portion 29. Thus, the refrigerant flowing into from the introduction port 24 does not directly flow out from the discharge port 25.

As shown in FIG. 3, the raised portion inner space 42 is a space enclosed by the inclined walls 27, the connecting wall 28 and the guide portion 29 and communicates with the inlet space 41 and the connection space 43. The refrigerant circulates in the raised portion inner space 42 formed in the raised portion 26 by the guide portion 29. Thus, the transistors 14 fixed to the inclined walls 27 of the raised portion 26 are cooled by the refrigerant circulating in the raised portion inner space 42.

As shown in FIG. 4, the connection space 43 is a space formed on a side opposite to the inlet space 41 across the guide portion 29 and communicates with the raised portion inner space 42 and the flat space 44.

As shown in FIGS. 2 and 5, the flat space 44 is a flat space formed between the cooling wall 22 and the heat insulating wall 21. The discharge port 25 is open to the flat space 44 and the flat space 44 communicates with the connection space 43. Heat generating elements such as the capacitor and the coil arranged in the inner space 11 of the motor controller 3 are cooled by the refrigerant circulating in the flat space 44 via the cooling wall 22. A cooling fin may be formed on the cooling wall 2 to increase a contact area between the cooling wall 22 and air in the inner space 11. Further, a partition for guiding the refrigerant into the flat space 44 may be provided so that the refrigerant uniformly flows in the flat space 44.

Next, a cooling action by the refrigerant circulating in the cooling unit 5 is described.

The refrigerant supplied from an unillustrated refrigerant supply device flows into the inlet space 41 through the introduction port 24. The refrigerant flowing into the inlet space 41 has a flowing direction changed by the guide portion 29, flows in a direction toward the motor controller 3 (upwardly of in FIGS. 2 and 4) and flows into the raised portion inner space 42. The refrigerant flowing into the raised portion inner space 42 cools the transistors 14 fixed to the inclined walls 27 via the inclined walls 27. The refrigerant circulating in the raised portion inner space 42 flows into the flat space 44 through the connection space 43. The refrigerant flowing into the flat space 44 cools the heat generating elements such as the capacitor and the coil arranged in the inner space 11 of the motor controller 3 via the cooling wall 22. Thereafter, the refrigerant is returned to the refrigerant supply device through the discharge port 25.

According to the above embodiment, the following effects are exhibited.

Since the raised portion 26 projecting into the inner space 11 of the motor controller 3 is provided in the cooling unit 5, the inner space 11 and the circuit elements such as the transistors 14, the capacitor and the coil arranged in the inner space 11 are efficiently cooled. As a result, an increase in the temperature of an electronic circuit fixed to the board can be suppressed and the motor can be operated with a higher output for a longer time. Particularly, the transistors 14 fixed to the inclined walls 27 are more efficiently cooled by the refrigerant via the inclined walls 27.

Further, since the cooling unit 5 is arranged while being separated from the motor 2 by the predetermined clearance 31 without directly contacting the motor 2, air present between the cooling unit 5 and the motor 2 acts as a heat insulating layer and the transfer of the heat of the motor 2 and the heat of the pump 1 to the motor controller 3 via the cooling unit 5 can be prevented. Also, heat transfer can be further prevented by introducing cooling air and traveling air to the clearance 31 between the cooling unit 5 and the motor 2. As a result, an increase in the temperature of the electronic circuit fixed to the board can be suppressed and the motor can be operated with a higher output for a longer time.

Further, since the connecting portion 4 connecting the motor controller 3 and the motor 2 is connected to the motor 2 in the part distant from the part where the pump 1 is coupled to the motor 2, the heat of the pump 1 is difficult to transfer to the motor controller 3. As a result, the transfer of the heat of the pump 1 to the motor controller 3 can be suppressed and an increase in the temperature of the electronic circuit fixed to the board can be suppressed.

Further, by providing the raised portion 26 projecting into the inner space 11 of the motor controller 3 in the cooling unit 5, the inner space 11 extending from the drive circuit board 12 toward the cooling unit 5 is enlarged. By arranging the relatively large circuit elements such as the coil and the capacitor in this enlarged inner space 11 in a concentrated manner, the circuit elements can be arranged in a compact manner, effectively utilizing the inner space 11. Further, since the raised portion 26 includes two inclined walls 27, even if there are many transistors 14, these can be arranged in a compact manner.

Further, even if the interval between the drive circuit board 12 to which the terminal portion 14b of the transistor 14 is fixed and the inclined wall 27 to which the main body portion 14a of the transistor 14 is fixed changes due to a thermal expansion difference, a certain degree of displacement is absorbed by increasing or decreasing the angle of the bent portion 14c formed on the terminal portion 14b. Thus, a force acting on the soldered part of the drive circuit board 12 and the terminal portion 14b is reduced when the thermal expansion difference occurs as compared with the case where a flat surface to which a main body portion of a transistor is fixed and a board to which a terminal portion is fixed perpendicularly intersect and the terminal portion is formed with no bent portion. As a result, it can be prevented that a contact state between the terminal portion 14b and the drive circuit board 12 becomes defective.

Embodiments of the present invention were described above, but the above embodiments are merely examples of applications of the present invention, and the technical scope of the present invention is not limited to the specific constitutions of the above embodiments.

For example, although the electric pump 100 according to the above embodiment sucks and discharges the hydraulic oil as working fluid, water or the like may be sucked and discharged as the working fluid instead of this.

This application claims priority based on Japanese Patent Application No. 2014-84957 filed with the Japan Patent Office on Apr. 16, 2014, the entire contents of which are incorporated into this specification.

1. An electric pump for discharging working fluid, comprising:
a pump configured to suck, pressurize and discharge the working fluid;
a motor coupled with the pump and configured to drive the pump;
a motor controller arranged laterally to the motor and configured to control the drive of the motor; and
a cooling unit arranged between the motor and the motor controller and configured to cool the motor controller by a refrigerant circulating inside,
wherein the cooling unit includes a raised portion projecting into an inner space of the motor controller, the raised portion being formed with a flow passage for the circulation of the refrigerant inside.

2. The electric pump according to claim 1, wherein:
the cooling unit further includes a guide portion configured to guide the refrigerant to pass through the flow passage formed in the raised portion.

3. The electric pump according to claim 1, wherein:
the raised portion has an inclined surface inclined with respect to a direction perpendicular to a board arranged in the motor controller; and
the electric pump further comprises a circuit element including a terminal portion fixed to the board and a main body portion fixed to the inclined surface.

4. The electric pump according to claim 1, further comprising:
a heat insulating layer provided between the motor and the cooling unit and configured to suppress heat transfer from the motor to the cooling unit.

5. The electric pump according to claim 1, further comprising:
a connecting portion configured to electrically connect the motor controller and the motor and fix the motor controller to the motor,
wherein the connecting portion is connected to the motor in a part distant from a part where the pump is coupled to the motor.
